(19) United States
(12) Patent Application Publication
(10) Pub. No.: US 2005/0183944 A1
(43) Pub. Date: Aug. 25, 2005

(54) Reducing stress in coatings produced by physical vapour deposition

(76) Inventors: Xu Shi, Singapore (SG); Li Kang Cheah, Singapore (SG)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/036,986

(22) Filed: Jan. 19, 2005

(30) Foreign Application Priority Data
Jan. 21, 2004 (GB) 0401295.1

(51) Int. Cl. H05H 1/24; C23C 14/32

(52) U.S. Cl. 204/192.12; 427/569; 204/298.02

(57) ABSTRACT

Coatings are deposited using arc-based deposition methods using a large negative bias on the substrate, of −1,500 V or more negative, which is varied during deposition, resulting in reduced stress in the coating.

### TECHNICAL FIELD

The invention relates to reducing stress in coatings deposited with arc deposition devices, especially those which enable a substrate to be biased with a large negative voltage.

### BACKGROUND

A number of plasma-based deposition methods have in recent years replaced sputtering systems as the desirable means of depositing thin coatings on a wide range of substrates.

It is known to use voltage-biasing of a substrate during deposition of a coating via physical vapour deposition (PVD) processes. This voltage biasing tends to be at a constant level throughout the deposition phase, at potentials of about −1,000 V or about −600 V. For example, Ionbond® produces a range of PVD devices, one of which has the designation ‘PVD-350’, in which a substrate is biased at a constant voltage of −1,000 V. This biasing prevents any build-up of positive electrostatic potential and enables films of acceptable depth to be deposited.

A problem with coatings produced by this and other known methods is that whilst they can have very high levels of hardness, there is also a high level of stress in the coating. This restricts the coating depth and the possible applications for which the coated products can be used.

There is hence a need for coatings of a lower stress, enabling the coatings to stick to the substrate with greater ease, be more flexible (i.e. less brittle), have a greater thickness and/or have an improved consistency.

There is a need to provide a method and apparatus for deposition of coatings having reduced stress than hitherto possible. There is a further need to provide a coating having an improved stress-level is produced. There is a further need to enable a thicker coating to be deposited onto the substrate, with a higher consistency than has been previously achieved.

### SUMMARY

The invention is based upon the use of a large negative bias applied to a substrate. Accordingly, the present invention provides a method for coating a substrate, comprising:
creating a plasma of a coating material;
depositing plasma on the substrate; and
biasing the substrate at −1,500 V or more negative.

The use of this bias results in reduced stress of the applied film. In examples below, we have biased a titanium test-plate at −4,500 V and observed considerably lower stress levels in the applied film than those achieved when using a known fixed bias.

Another feature of the invention is application of a bias that varies during the deposition process, and a further method for coating a substrate comprises:
creating a plasma of a coating material;
depositing plasma on the substrate; and
biasing the substrate using a variable bias.

It is not necessary to apply a constant high magnitude bias to achieve stress reduction, and in this embodiment of the invention, variation of the bias voltage, with the bias returning to or hear to zero between peaks, also enables reduction in stress of the deposited films.

Preferably, deposition of a coating is carried out whilst both varying the bias on the substrate and applying a bias of −1,500 V or more negative.

In use of a method of the invention, the bias applied to the substrate is suitably up 5 to −10,000 V, preferably up to −5,000 V. Whilst a higher magnitude peak bias may be applied, we have found stress reduction to be achieved within these limits. The bias is further suitably −2,000 V or more negative. It is particularly preferred that the bias is in the range of from −2,000 V to −4,000 V for filtered cathodic vacuum arc (FCVA) sources and from −2,000 V to −3,000 V for other arc sources.

Methods of the invention employ a variable or pulsed bias, varying from large negative values to zero or near zero. After peaking at, say, about −1,500 V the bias can return to much smaller values, such as at −300 V or less negative, preferably −200 V or less negative. This can to a certain extent depend upon the power supply used, and in examples below the pulse generally returns from its peak to a value from about −100 V to zero, going transiently positive on occasion. The variation in bias in the examples follows an approximately square wave pattern, though other variations are also suitable, including regular and irregular wave forms.

During deposition, the pulse duration and frequency typically follows a pre-set pattern. The pulse duration is generally short, and can be from 1-50 us. For direct arc sources, the pulse duration is preferably from 1-20 μs, more preferably from 5-10 μs. For FCVA sources, the pulse duration is preferably from 10-40 μs, more preferably from 15-25 μs. The frequency is generally rapid, of a few hundred or thousand pulses per second. A preferred method comprises pulsing the bias on the substrate at a frequency of up to 10 kHz, preferably from 1-3 kHz, more preferably from 1.5-2.5 kHz.

In embodiments of the present invention, the power supply has come from Nanofilm Technologies International (NTI), and is termed a “high voltage pulse generator” (HVPG). However, the skilled person will be aware that any power supply can be utilised that is capable of biasing a substrate as herein described. We have deposited coatings of titanium nitride and tetrahedral amorphous carbon (ta-C) onto test substrates using various biasing voltages, pulse durations and frequency of pulses. For example, in one set-up, the HVPG was set to pulses of −4,500 V with a duration of 20 μs and a frequency of 10 kHz We then tested the stress of the titanium nitride coatings produced by our pulsed-biasing method, and found them to be in the range of 1-2 GPa, commonly about 1 Gpa. This compares favourably to the stress of titanium nitride coatings produced without pulsed biasing, which we found to have a stress of at least 3 GPa. The invention thus enables coatings to be deposited with low stress levels. This allows thicker coatings to be deposited, as prior art coatings are so brittle that they will not adhere to substrates once their depth exceeds certain values. This increases the application of this coating technology, as reduced stress films can now be applied to more flexible substrates (prior art films would peel away upon flexing).

The method is especially suited for producing coatings using arc-based deposition devices and methods, and hence, in a particular method of the invention, pulsed, large negative biasing of a substrate is carried out in a method for coating a substrate in an arc deposition apparatus, the apparatus comprising a vacuum chamber, a target, and an anode and a cathode for creating the plasma from the target.

In direct arc deposition, the target material is preferably a metal, and good results have been obtained using a target selected from titanium, chromium, aluminium, gallium or mixtures or alloys of any of the aforementioned. Biasing can also be applied when making composite or compound coatings, and a further method of the invention comprises introducing a gas into the vacuum chamber to form a coating on the substrate which is a compound of the gas and the target. Suitable gases include nitrogen and oxygen.

In FCVA deposition, the target material is preferably graphite, used for production especially of ta-C coatings, and metals can also be employed.

The invention further provides apparatus for coating a substrate in accordance with the methods described, and hence an apparatus of the invention comprises a vacuum chamber, an anode and cathode assembly for generating a plasma from a target and depositing plasma on the substrate to form a coating, and a power supply for biasing the substrate at −1,500 V or more negative. A further apparatus comprises a vacuum chamber, an anode and cathode assembly for generating a plasma from a target and depositing plasma on the substrate to form a coating, and a power supply for applying a variable bias to the substrate. Preferably, the power supply of the apparatus can both apply the large negative bias and vary the bias as per the methods described above.

In an example of use of the method and apparatus, a titanium target is placed in electrical contact with the cathode of an arc deposition apparatus. A substrate is located at the substrate station and the chamber is evacuated to about 1 μTorr. Nitrogen gas is introduced into the chamber to an operating pressure of about 1-20 mTorr, and preferably 3 mTorr. An arc is then struck, and a deposit of titanium nitride is coated onto the substrate. The substrate is biased during deposition at from −2,000 V to −3,000 V, at a frequency from 1-3 kHz and using a pulse duration of from 5-10 μs. Deposition is continued until a coating of about 2-3 μm is achieved. After deposition, the stress of the coating is generally from 1-2 GPa, and the hardness generally about 2,500 kg/mm².

In a further example of use of the method and apparatus, a graphite target is placed in electrical contact with the cathode of an FCVA deposition apparatus. A substrate is located at the substrate station and the chamber is evacuated to about 1 μTorr. No gas is introduced. An arc is then struck and a deposit of ta-C is coated onto the substrate. The substrate is biased during deposition at from −2,000 V to −4,000 V, at a frequency from 1.5-2.5 kHz and using a pulse duration of from 15-25 μs. Deposition is continued until a coating thickness of about up to 10 μm is achieved. After deposition, the stress of the coating is generally less than 1 GPa, with a hardness of generally about 2540 GPa and wear resistance of generally about 1×10⁻⁸-3×10⁻⁸ mm³/Nm.

In a further embodiment of the invention, an FCVA coating process is carried out in at least two phases. The first phase employs a substrate bias of −3,000 V to −4,000 V at a frequency of 1.5-2.5 kHz and using a pulse duration of 15-25 μs. The second phase employs a substrate bias of −2,000 V to −3,500 V at a frequency of 1.5-2.5 kHz and using a pulse duration of 15-25 μs.

The coatings provided by the present invention can be used in a variety of applications, e.g. anvils can be coated, or tool punches can be coated to increase the lifespan of the punch, or semiconductors and media devices can be coated to afford greater protection. The advantages of the biasing of the invention include the production of a coating of lower stress, which enables flexibility and/or a thicker coating to be deposited.

Generally, the invention provides use of a bias voltage of −1,500 V or more negative for reducing stress in a coating deposited using an arc deposition apparatus and/or use of a variable bias voltage for reducing stress in a coating deposited using an arc deposition apparatus.

### BRIEF DESCRIPTION OF DRAWINGS

Embodiments of the invention are now described with reference to the accompanying table and drawings in which:

Table 1 shows various combinations of bias parameters that have been achieved using the high voltage pulse generator;

FIG. 1 shows an output pulse waveform used to bias a substrate in a method of the invention; and

FIG. 2 shows an output pulse waveform used to bias a substrate in a method of the invention.

### DETAILED DESCRIPTION

We modified an existing PVD device so as to apply a bias to the substrate in accordance with the invention, using a power supply obtained from Nanofilm Technologies International (NTI), termed a “high voltage pulse generator” (HVPG). The power unit has a control panel on which the parameters can be manually set. Also employed is a switching device insulated gate bipolar transistor (IGBT) which is protected against current overloads and short circuits. The generator assembly is also equipped with an output fuse.

The output range of the pulse generator is up to −10,000 V, preferably −5,000 V, and more preferably −2,000 V to −4,000 V, with the pulses lasting from between 1-50 μs; for direct arc sources preferably from between 1-20 μs, more preferably from between 5-10 μs, and for FCVA sources preferably from between 10-40 μs, more preferably 15-25 μs; and at a frequency of up to 10 kHz, preferably from 1-3 kHz, more preferably from 1.5-2.5 kHz.

The HVPG was associated with the PVD device, and connected to the substrate, most commonly via the substrate holder. During operation of the PVD device, the HVPG was set to deliver pulses of large negative voltage to the substrate. The HVPG was started and stopped either manually or via remote.

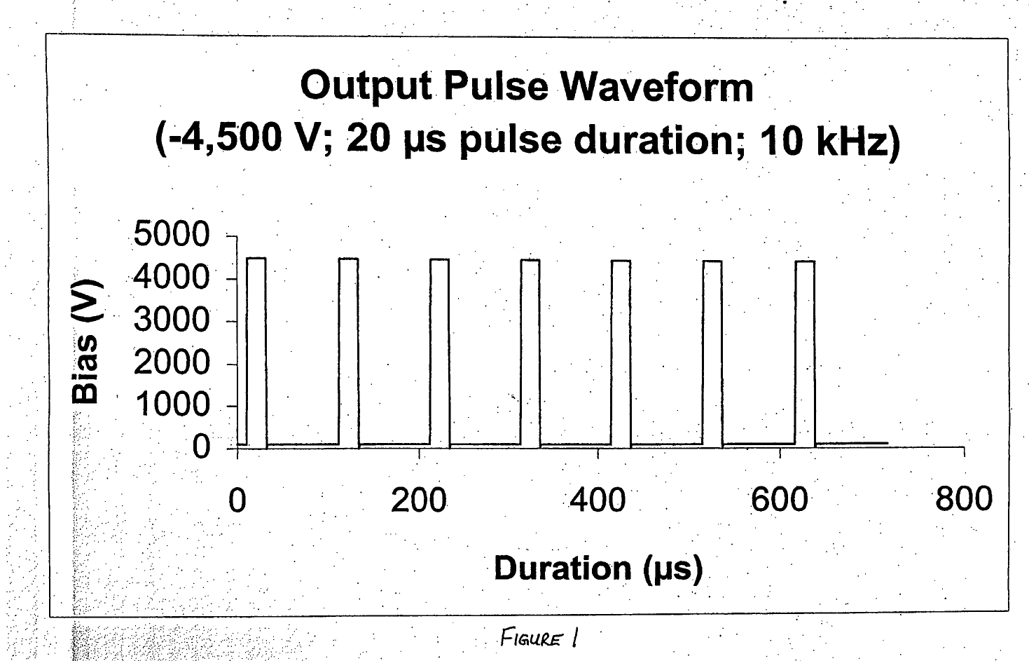

We deposited a coating of titanium nitride onto a test substrate (in this case, titanium plates approximately 5 cm x 10 cm, 0.5 cm in depth) using a bias illustrated schematically in FIG. 1—i.e. the HVPG was set to pulses of −4,500 V with a duration of 20 μs and a frequency of 10 kHz.

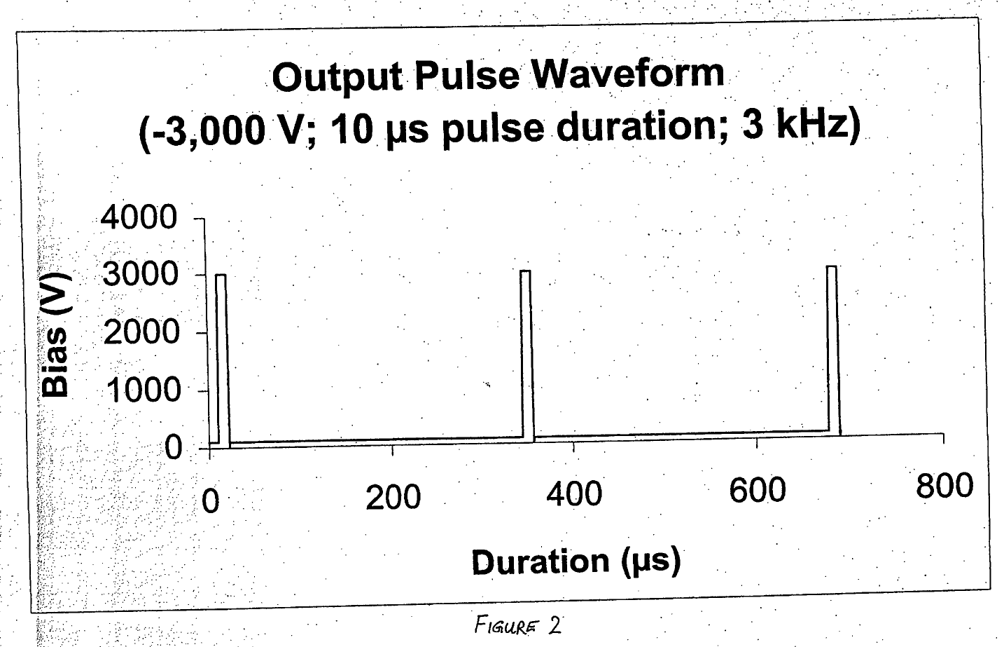

Similarly, we used a bias illustrated schematically in FIG. 2—i.e. the HVPG was set to pulses of −3,000 V with a duration of 10 μs and a frequency of 3 kHz.

We then tested the stress of the titanium nitride coatings, produced by our pulsed-biasing method, on the various test plates and found them to have values that were in the range of 1-2 GPa. The stress of a number of the tested coatings were found to have a value close to 1 GPa. This compares favourably to the stress of titanium nitride coatings produced without pulsed biasing, which we found to have a stress of at least 3 GPa.

We also tested the stress of the ta-C coatings, produced by our pulsed-biasing method, on the various test plates and found them to have values that were less than 1 GPa. The hardness was about 25-40 GPa and wear resistance was about 1×10⁻⁸ −3×10⁻⁸ Mm³/Nm.

Thus, the advantages of biasing of the invention include the production of a coating of lower stress, which enables flexibility and/or a thicker coating to be deposited.

TABLE 1

| Bias (V) | Duration (μs) | Frequency (kHz) |
|---|---|---|
| −4,500 | 20 | 10 |
| −4,500 | 2 | 10 |
| −4,500 | 2 | 1 |
| −3,000 | 10 | 3 |
| −3,000 | 5 | 1 |
| −2,000 | 8 | 2 |
| −2,000 | 10 | 2 |
| −4,000 | 25 | 2.5 |

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. A method for coating a substrate, comprising:
creating a plasma of a coating material;
depositing plasma on the substrate; and
biasing the substrate at −1,500 V or more negative.

2. A method for coating a substrate, comprising:
creating a plasma of a coating material;
depositing plasma on the substrate; and
biasing the substrate using a variable bias,

3. A method according to claim 2, further comprising:
biasing the substrate at −1,500 V or more negative.

4. A method according to claim 1 or claim 2, comprising:
biasing the substrate at up to −10,000V.

5. A method according to claim 4 comprising:
biasing the substrate at up to −5,000 V.

6. A method according to any of claims 1 or claim 2 comprising:
biasing the substrate at −2,000 V or more negative.

7. A method according to claim 6 comprising:
biasing the substrate at from −2,000V to −4,000V.

8. A method according to claim 1 or claim 2, comprising:
pulsing the bias on the substrate at a frequency of up to 10 kHz.

9. A method according to claim 8, wherein the frequency is from 1-3 kHz.

10. A method according to claim 8, wherein the pulse duration is from 1-25 μs.

11. A method according to claim 10, wherein the pulse duration is from 5-10 μs.

12. A method according to claim 1 or claim 2 for coating a substrate in an arc deposition apparatus, the apparatus comprising a vacuum chamber, a target, and an anode and a cathode for creating the plasma from the target.

13. A method according to claim 12 wherein the apparatus comprises a filtered cathodic vacuum arc source.

14. A method according to claim 12 wherein the target is a metal.

15. A method according to claim 12 wherein the target is graphite.

16. A method according to claim 12, wherein the target comprises titanium, chromium, aluminium, gallium or mixtures or alloys of any of the aforementioned.

17. A method according to 12, comprising introducing a gas into the vacuum chamber to form a coating on the substrate which is a compound of the gas and the target.

18. Apparatus for coating a substrate, comprising a vacuum chamber, an anode and cathode assembly for generating a plasma from a target and depositing plasma on the substrate to form a coating, and a power supply for biasing the substrate at −1,500 V or more negative.

19. Apparatus for coating a substrate, comprising a vacuum chamber, an anode and cathode assembly for generating a plasma from a target and depositing plasma on the substrate to form a coating, and a power supply for applying a variable bias to the substrate.

20. Apparatus according to claim 19, wherein the power supply applies a bias of −1,500 V or more negative to the substrate.

21. Apparatus according to claim 18, comprising a power supply for biasing the substrate at from −2,000 V to −4,000 V.

22. Apparatus according to claim 18, comprising a power supply for pulsing the bias voltage at a frequency of from 1-3 kHz.

23. Apparatus according to claim 18, comprising a power supply for pulsing the bias to the substrate at a pulse duration of from 5-10 μs.

24. Use of a bias voltage of −1,500 V or more negative for reducing stress in a coating deposited using an arc deposition apparatus.

25. Use of a bias voltage of −2,000 V to −4,000 V for reducing stress in a coating deposited using an FCVA source.

26. Use of a variable bias voltage for reducing stress in a coating deposited using an arc deposition apparatus.
